(19) United States
(12) Patent Application Publication
(10) Pub. No.: US 2024/0365533 A1
(43) Pub. Date: Oct. 31, 2024

(54) SEMICONDUCTOR DEVICE, FABRICATION METHOD OF SEMICONDUCTOR DEVICE AND MEMORY SYSTEM

(71) Applicant: YANGTZE MEMORY TECHNOLOGIES CO., LTD., Wuhan (CN)

(72) Inventors: Ya WANG, Wuhan (CN); FanDong LIU, Wuhan (CN); Zijin YANG, Wuhan (CN); Wenxiang XU, Wuhan (CN); Dongmen SONG, Wuhan (CN)

(21) Appl. No.: 18/624,911

(22) Filed: Apr. 2, 2024

(30) Foreign Application Priority Data
Apr. 28, 2023 (CN) 2023105036047

(51) Int. Cl. H10B 12/00

(52) U.S. Cl. CPC H10B 12/34; H10B 12/053

(57) ABSTRACT

Implementations of the present application disclose a semiconductor device, a fabrication method of a semiconductor device and a memory system. The semiconductor device includes a plurality of word line groups and separating structures disposed between two adjacent word line groups. The word line groups and the separating structures extend in the first lateral direction. In the first lateral direction, the length of a word line group is greater than the length of a separating structure; wherein a word line group includes two word lines and two partition structures. In a same word line group, the word lines and the partition structures are disposed as a closed loop. In the second lateral direction perpendicular to the first lateral direction, there are overlaps between partition structures and separating structures.

### CROSS-REFERENCE TO RELATED APPLICATIONS

The present application claims priority to Chinese Patent Application No. 2023105036047, which was filed Apr. 28, 2023, is titled “SEMICONDUCTOR DEVICE, MANUFACTURING METHOD AND STORAGE SYSTEM OF SEMICONDUCTOR DEVICE,” and is hereby incorporated herein by reference in its entirety.

### TECHNICAL FIELD

The present application is related to the semiconductor technology field, in particular to a semiconductor device and a fabrication method thereof, as well as a memory system.

### BACKGROUND

A semiconductor device includes a memory structure and a word line group and bit lines connected with the memory structure. The word line group may be a loop structure disposed around a trench and broken into two separate word lines by two partition structures distributed on two sides of the trench.

### SUMMARY

The present application provides a semiconductor device, a fabrication method of a semiconductor device and a memory system in order to address the problem of failing to be disconnected and remaining in connected state for two word lines in a word line group in the fabrication process of the semiconductor device.

An implementation of the present application provides a semiconductor device comprising:
a plurality of word line groups and separating structures disposed between two adjacent word line groups, the word line groups and the separating structures extending in a first lateral direction, and a length of the word line group being greater than a length of the separating structure;
wherein the word line group comprises two word lines and two partition structures, in a same word line group, the word lines and the partition structures are disposed alternatingly as a closed loop, and in a second lateral direction perpendicular to the first lateral direction, there are overlaps between the partition structures and the separating structures.

In some implementations, an orthogonal projection of the partition structure in the second lateral direction is within the separating structure.

In some implementations, in a top view direction of the semiconductor device, the partition structures and side edges of ends of the separating structures are disposed with intervals.

In some implementations, in the second lateral direction, a distance d1 between the partition structure and a side edge of an end of the separating structure is greater than or equal to 200 nm.

In some implementations, the separating structure comprises a gas cavity.

In some implementations, the separating structure comprises a metal section.

In some implementations, the separating structure comprises a metal section, a first insulating section and a second insulating section;

wherein the first insulating section is disposed on side walls and bottom of the metal section, and the second insulating section is disposed on a top of the metal section and a top of the first insulating section.

In some implementations, the semiconductor device further comprises an etch stop section and a planar section at a bottom of the word line group;

wherein the etch stop section is disposed at a bottom of the word lines and the planar section is filled in the etch stop section.

In some implementations, the semiconductor device further comprises a plurality of channel structures disposed with intervals in the first lateral direction between adjacent word line groups and separating structures.

In some implementations, the partition structures comprise an insulating material.

Implementations of the present application further provides a fabrication method of a semiconductor device comprising:
providing a substrate;
forming a plurality of first trenches extending in a first lateral direction and a plurality of second trenches extending in the first lateral direction and arranged alternatingly in a second lateral direction in the substrate, wherein the first lateral direction is perpendicular to the second lateral direction and a length of the first trench is greater than a length of the second trench;
forming a word line layer on side walls of the first trench;
forming a first insulating layer on the substrate to cover the word line layer;
forming a plurality of first openings in the first insulating layer to expose the word line layer, wherein the first openings overlap the second trenches in the second lateral direction;
removing exposed word line layer to form partition structures and form a word line group by a remained word line layer.

In some implementations, an orthogonal projection of the partition structure in the second lateral direction with respect to the second trench is within the second trench, and in a top view direction of the semiconductor device, the partition structure and a side edge of an end of the second trench are disposed with intervals.

In some implementations, the operation of removing exposed word line layer to form partition structures comprises:
removing the exposed word line layer; and
forming a second insulating layer on the substrate to fill the first openings, thereby forming partition structures.

In some implementations, two of the first openings correspond to one of the first trenches.

In some implementations, before the operation of forming the word line layer on side walls of the first trench, the method further comprises:
forming a third insulating layer in the second trench;
forming second openings in the third insulating layer by patterning to form the first insulating sections; and
filling metal sections in the second openings.

In some implementations, after the operation of filling the metal sections in the second openings, the method further comprises:
forming second insulating sections on the metal sections and the first insulating sections;
wherein the first openings expose the second insulating sections and the substrate.

In some implementations, the operation of forming the word line layer on side walls of the first trench comprises:
forming a fourth insulating layer on side walls and bottom of the first trench;
forming a etch stop section on side walls and bottom of the first trench;
forming a planar section inside the etch stop section;
forming a word line material layer in the first trench; and
forming the word line material layer into a word line layer disposed on side walls of the first trench by patterning.

In some implementations, before the operation of forming the plurality of first trenches extending in the first lateral direction and the plurality of second trenches extending in the first lateral direction in the substrate, the method further comprises:
forming a plurality of third trenches extending in the second lateral direction in the substrate;
wherein the plurality of first trenches, the plurality of second trenches and the plurality of third trenches intersect each other to form a plurality of channel structures that are disposed with intervals in the first lateral direction between adjacent word line groups and second trenches.

An implementation of the present application further provides a memory system comprising:
a semiconductor device as described above, comprising a plurality of word line groups and separating structures disposed between adjacent word line groups, the word line groups and the separating structures extending in the first lateral direction, in the first lateral direction, the length of a word line group being greater than the length of a separating structure, herein the word line group including two word lines and two partition structures, in a same word line group, the word lines and the partition structures being disposed as a closed loop, in the second lateral direction perpendicular to the first lateral direction, there being overlaps between partition structures and separating structures; and
a controller coupled with the semiconductor device and configured to control the semiconductor device to implement data writing and reading operations.

With the semiconductor device provided in implementations of the present application, having the partition structures and the separating structures to overlap in the second lateral direction perpendicular to the first lateral direction allows the part of the word line group between the two partition structures to be far away from the shifting regions of the separating structures on at least a side in the first lateral direction, such that there is a reduced risk of patterning shift for the part of the word line group between the two partition structures and it is easier to etch through it. Therefore, parts of the two word lines of the word line group in the overlapping region remain in separated state, thereby reducing the risk of remaining connected for the two word lines of the word line group due to the patterning shifts in the process of forming the word line group by etching.

Further, by having the partition structures and the separating structures to overlap in the second lateral direction perpendicular to the first lateral direction, the separating structures can have a longer length in the first lateral direction, thereby increasing the effective area and allowing the semiconductor device to from more cell transistors. At the same time, it is also possible to keep the CUT PH OVL constant.

### BRIEF DESCRIPTION OF THE DRAWINGS

In order to explain the technical solutions in implementations of the present application more clearly, accompanying drawings required in describing implementations will be described in brief below. The below described drawings are only some implementations of the present application and other drawings may be obtained according to these drawings without any creative work.

FIG. 1 is a structure diagram of a first structure of a semiconductor device provided in implementations of the present application;

FIG. 2 is a sectional view along A-A direction in FIG. 1, in accordance with implementations of the present application;

FIG. 3 is a structure diagram of a substrate provided in implementations of the present application after a first trench is formed;

FIG. 4 is a structure diagram of a substrate provided in implementations of the present application after a first trench, a second trench, a third trench and a third insulating layer are formed;

FIG. 5 is a sectional view along B-B direction in FIG. 4, in accordance with implementations of the present application;

FIG. 6 is a sectional view of the substrate provided in implementations of the present application after a first insulating section is formed in the second trench;

FIG. 7 is a sectional view of the substrate provided in implementations of the present application after a metal section is formed in the second trench;

FIG. 8 is a sectional view of the substrate provided in implementations of the present application after a second insulating section, a fourth insulating layer, a etch stop section and a planar section are formed in the second trench;

FIG. 9 is a structure diagram of the substrate provided in implementations of the present application after a word line material layer is disposed in the first trench;

FIG. 10 is a sectional view along C-C direction in FIG. 9, in accordance with implementations of the present application;

FIG. 11 is a structure diagram after the word line material layer is formed into a word line layer and a first insulating layer as provided in implementations of the present application;

FIG. 12 is a sectional view along D-D direction in FIG. 11, in accordance with implementations of the present application;

FIG. 13 is a structure diagram after a first opening is formed in the first insulating layer as provided in implementations of the present application;

FIG. 14 is a sectional view along E-E direction in FIG. 13, in accordance with implementations of the present application;

FIG. 15 is a structure diagram after removing a part of the word line layer exposed by the first opening as provided in implementations of the present application;

FIG. 16 is a sectional view along F-F direction in FIG. 15, in accordance with implementations of the present application;

FIG. 17 is a structure diagram of an implementation of a memory system provided in implementations of the present application;

FIG. 18 is a structure diagram of an electronic apparatus provided in implementations of the present application;

FIG. 19 is a structure diagram corresponding to processes in the method of fabricating a semiconductor device provided in implementations of the present application.

memory system 1; semiconductor device 10; substrate 11; channel structure 110; first trench 111; second trench 112; third trench 113; word line group 12; word line 121; word line layer 120; etch trench 1200; word line segment 1201; word line material layer 1202; leading-out structure 122; partition structure 123; first insulating layer 13; first opening 131; second insulating layer 14; third insulating layer 15; first insulating section 151; second opening 152; fourth insulating layer 16; etch stop section 17; planar section 18; partition structure 19; metal section 191; second insulating section 193; overlapping region S; shifting region M; controller 20; host 30; central processor 2; electronic apparatus 3.

### DETAILED DESCRIPTION

The technical solution in implementations of the present application will be described below clearly and completely with reference to accompanying drawings in implementations of the present application. However, the described implementations are only partial implementations rather than all implementations of the present application. Based on the implementations of the present application, all other implementations obtained by those skilled in the art without any creative work fall within the scope of the present application. Furthermore, it will be understood that implementations as described herein are merely used for illustrating and explaining the present application rather than limiting the present application. In the present application, unless otherwise stated, orientation terms such as “upper” and “lower” typically refer to the upper and lower parts of a device in practical use or operation state which are specifically the drawing direction in the figures; while “inner” and “outer” are used with respect to the profile of a device.

A semiconductor device typically includes a memory cell transistor and a word line group and bit lines (not shown) connected with the memory cell transistor. The word line group is configured to supply word line voltages to the memory structure and control on or off of the channel region of each memory cell transistor by the word line voltage. The bit lines are configured to implement reading or writing operations while each memory cell transistor is turned on.

Herein, the word line group may be of a loop structure that is broken into two word lines by two partition structures. In the process of forming the two word lines in the word line group and the two partition structures, the two word lines of the word line group tend to remain in connected state, resulting in conduction between the two word lines of the word line group.

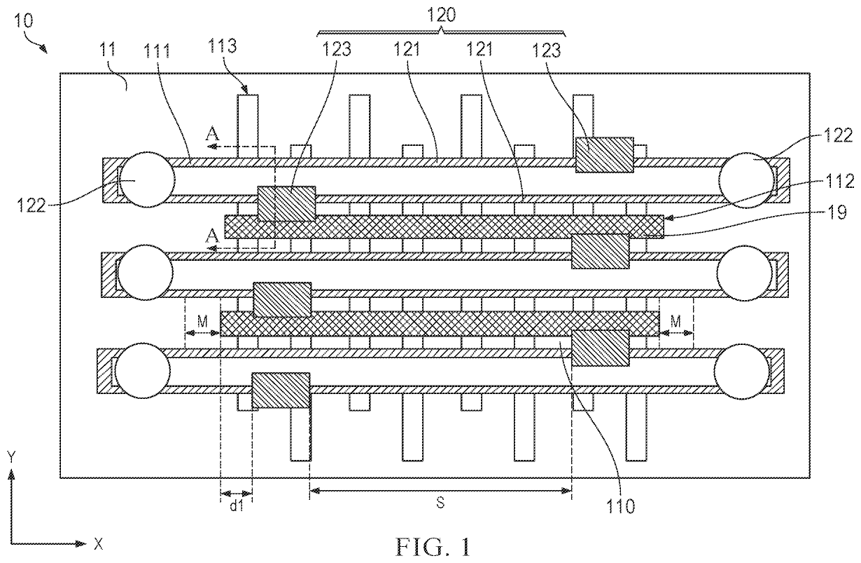

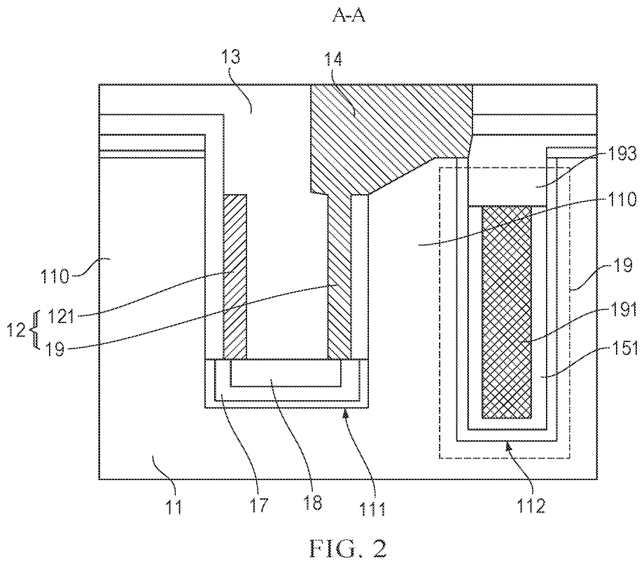

In order to avoid the above-described problem, an implementation of the present application provides a semiconductor device. As shown in FIGS. 1 and 2, the semiconductor device 10 includes a plurality of word line groups 12 and separating structures 19 between two adjacent word line groups 12. The word line groups 12 and the separating structures 19 extend in the first lateral direction (the direction parallel to X direction in FIG. 1) respectively. In the first lateral direction, the length of a word line group 12 is greater than the length of a separating structure 19. The separating structures 19 can isolate adjacent word line groups 12, thereby reducing signal influence between two adjacent word line groups 12.

Herein, in the second lateral direction perpendicular to the first lateral direction (the direction parallel to the Y direction in FIG. 1), the plurality of word line groups 12 are distributed with intervals successively. Separating structures 19 are disposed between two adjacent word line groups 12. The material for the word line groups 12 may be tungsten (W) or other metal materials.

Referring back to FIGS. 1 and 2, a word line group 12 includes two word lines 121 and two partition structures 123, and in the same word line group 12, the word lines 121 and the partition structures 123 are arranged alternatingly in a closed loop. The two partition structures 123 can separate ends of two word lines 121 in the word line group 12 such that the two word lines 121 of the word line group 12 remain separated.

Herein, the semiconductor device 10 includes a substrate 11, a plurality of word line groups 12 and separating structures 19 disposed between two adjacent word line groups 12. In some examples, the material for the substrate 11 may be silicon (Si). The substrate 11 includes a plurality of first trenches 111 extending in the first lateral direction and arranged successively with intervals in the second lateral direction that is perpendicular to the first lateral direction. Two word lines 121 of a word line group 12 are disposed on sidewalls of the first trench 111 and extend circumferentially along the first trench 111. The two word lines 121 of the word line group 12 are distributed successively along the circumferential direction of the first trench 111. The two partition structures 123 of a word line group 12 are distributed on two sides of the first trench 111 in the second lateral direction.

The substrate 11 further includes a plurality of second trenches 112 extending in the first lateral direction. The first trenches 111 and the second trenches 112 are arranged alternatingly in the second lateral direction. The length of the first trench 111 is greater than the length of the second trench 112. There are separating structures 19 disposed in the second trenches 112. That is, separating structures 19 are disposed respectively between each two adjacent word line groups 12.

In some implementations, in the second lateral direction perpendicular to the first lateral direction, there are overlaps between partition structures 123 and separating structures 19 so as to reduce the risk of interconnections between two word lines 121 of a word line group 12 at least to a certain degree.

In the fabrication process of the semiconductor device 10, researchers found out after studies that patterning shift might occur in the process of etching the substrate 11 to form word line groups 12, and the shifting regions M undergoing patterning shift are on two sides of a separating structure 19 in the first lateral direction. In the overlapping region S in which two word lines 121 of a word line group 12 overlap in the second lateral direction (a region between two partition structures 123 of a word line group 12), the gap between the two word lines 121 might not penetrate through the whole word line group 12, thereby causing partial connection between two word lines 121 of the word line group 12 in the overlapping region S.

Researchers found that the primary cause of patterning shift is as follows. While forming the word line groups 12 and the separating structures 19, due to the etching loading effect, random pattern shifts might occur in fixed regions, resulting in insufficient cut OVL windows for word lines 121 that is an inherent etching loading effect that can not be compensated for by lithographic process and can not be addressed by optimizing pattern design.

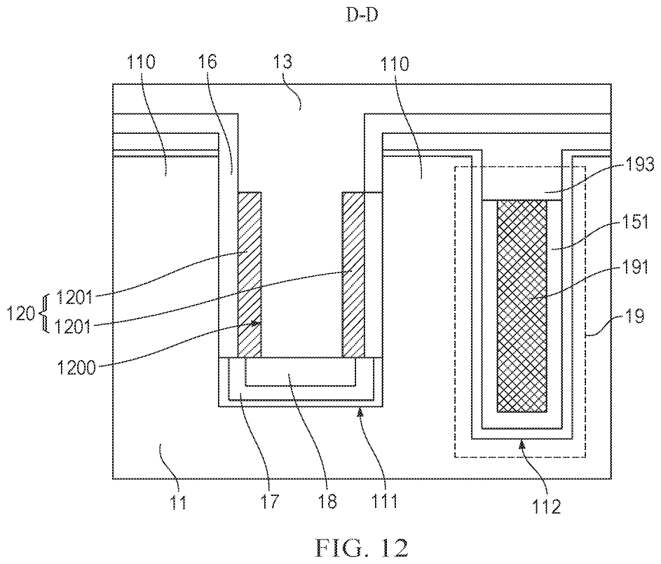

At the same time, the longer first trench 111 has a small critical dimension (CD) and a shallow depth at the ends of the shorter second trench 112 such that a planar insulating layer can not be formed at the bottom, which causes the first trench 111 to have a circular or arcuate bottom face at ends of the second trench 112 on which metal deposition is difficult. Therefore, while etching to form etch trenches 1200 (referring to FIG. 12), it is difficult to separate the two word lines 121 of the word line group 12 and there is a great risk of shortening the two word lines 121.

With the semiconductor device 10 provided in implementations of the present application, having the partition structures 123 and the separating structures 19 to overlap in the second lateral direction perpendicular to the first lateral direction allows the overlapping regions S to be far away from the shifting regions M of the separating structures 19 on at least a side of the first lateral direction, such that there is a reduced risk of patterning shift for parts of the two word lines 121 of the word line group 12 that are in the overlapping regions S. The gap between the two word lines 121 in the overlapping region S can penetrate through the whole word line group 12 such that parts of the two word lines 121 of the word line group 12 in the overlapping region S remain in separated state, thereby reducing the risk of remaining connected for the two word lines 121 of the word line group 12 due to the patterning shifts in the process of forming the word line group 12 by etching.

Further, by having the partition structures 123 and the separating structures 19 to overlap in the second lateral direction perpendicular to the first lateral direction, the separating structures 19 can have a longer length in the first lateral direction, thereby increasing the effective area and allowing the semiconductor device 10 to form more cell transistors. At the same time, it is also possible to keep the CUT PH OVL constant.

Herein, it is possible to have one partition structure 123 of the word line group 12 and the separating structures 19 to overlap, or have both partition structures 123 of the word line group 12 and the separating structures 19 to overlap. Of course, the latter can make parts of the word line group 12 that is in the overlapping region S to be far away from the shifting regions M of the separating structures 19 on both sides in the first lateral direction at the same time so as to further reduce the risk of interconnection between two word lines 121 of the word line group 12.

Additionally, it is possible to have a part of the partition structure 123 and the separating structures 19 to overlap, or have the entire partition structure 123 and the separating structures 19 to overlap. Of course, the latter can make the overlapping region S to be farther away from the shifting regions M so as to further reduce the risk of interconnection between two word lines 121 of the word line group 12.

In some implementations, as shown in FIG. 1, the orthogonal projection of a partition structure 123 in the second lateral direction is within a separating structure 19. That is, all partition structures 123 overlap the separating structures 19 such that parts of the word line group 12 that in the overlapping region are farther away from the shifting regions M so as to further reduce the risk of interconnection between two word lines 121 of the word line group 12.

Referring back to FIG. 1, in the top view direction of the semiconductor device 10, the partition structures 123 and the side edges of ends of the separating structures 19 are disposed with intervals. Therefore, it is possible to further increase the distance between the overlapping regions S and the shifting regions M so as to further reduce the risk of interconnection between two word lines 121 of the word line group 12.

Herein, in the second lateral direction, the distance d1 between a partition structure 123 and a side edge of an end of a separating structure 19 is greater than or equal to 200 nm so as to reduce the risk of interconnections between two word lines 121 of a word line group 12 as much as possible. The distance d1 between a partition structure 123 and a side edge of an end of a separating structure 19 may be 210 nm, 250 nm, 300 nm etc. in some examples, depending on the structure of the semiconductor device 10.

Of course, in the second lateral direction, the distance d1 between a partition structure 123 and a side edge of an end of a separating structure 19 is greater than 200 nm so as to reduce the risk of interconnections between two word lines 121 of a word line group 12 to a certain degree.

In some implementations, the length of a word line group 12 in the first lateral direction is less than or equal to 100 microns (100000 nm). The length of a partition structure 123 in the first lateral direction is greater than or equal to 200 nm or less than or equal to 700 nm. The distance between the two partition structures 123 of a word line group 12 is less than or equal to 98 microns (98000 nm).

The length of a separating structure 19 in the first lateral direction is less than or equal to 98 microns (98000 nm). The difference between the length of a word line group 12 in the first lateral direction and the length of a separating structure 19 in the first lateral direction is less than or equal to 2000 nm. In the second lateral direction, the distance between ends on the same side in the first lateral direction of the word line group 12 and the separating structure 19 is greater than or equal to 1100 nm and less than or equal to 1300 nm.

As shown in FIG. 1, the semiconductor component further includes two pick ups 122 disposed on the word line group 12. The two pick ups 122 are located on two ends of the word line group 12 in the first lateral direction and connected with the two word lines 121 of the word line group 12 in one-to-one correspondence.

In some implementations, as shown in FIG. 2, the separating structure 19 includes a metal section 191. The metal section 191 can provide a better isolation effect for two adjacent word line groups 12. As compared to the partition structure 123 using a gas cavity, the partition structure 123 including a metal section 191 can further address the device row hammer effect.

Herein, the metal section 191 is located in the second trench 112 and extends in the first lateral direction. The separating structure 19 includes a metal section 191, a first insulating section 151 disposed on sidewalls and bottom of the metal section 191 and a second insulating section 193 disposed on top of the metal section 191 and on top of the first insulating section 151.

In some examples, the first insulating section 151 is located at the bottom and periphery sidewalls of the metal section 191. The second insulating section 193 is disposed on top of the metal section 191, the first insulating section 151 and the substrate 11. The material for the metal section 191 may be titanium nitride (TiN) or other metal materials. The material for the second insulating section 193 may be silicon nitride (SiN) or other insulating materials.

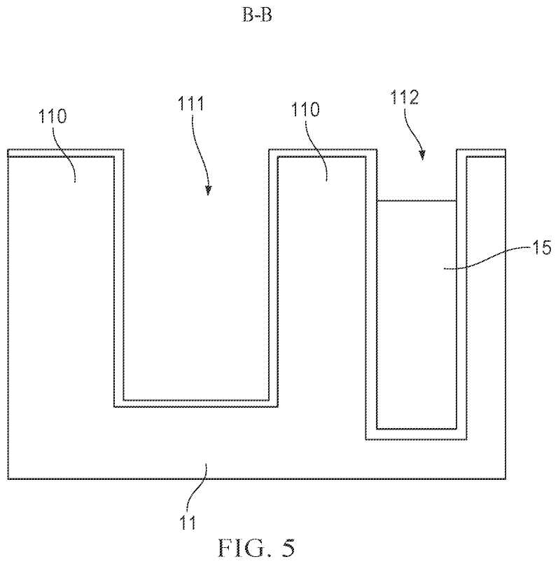

In other implementations, the separating structure 19 includes a gas cavity. Herein, it is possible to dispose a third insulating layer 15 (referring to FIG. 5) in a second trench 112 and form a second opening 152 by patterning to form a separating structure 19 having a gas cavity therein. The material for the third insulating layer 15 may be a high temperature oxide insulating material or other insulating materials.

In some implementations, the partition structures 123 include an insulating material. The partition structure 123 made by disposing insulating material between the two word lines of a word line group 12 can better keep the two word lines 121 of the word line group 12 in isolated state.

As shown in FIG. 2, the semiconductor device 10 further includes an etch stop section 17 and a planar section 18 located at the bottom of the word line group 12. The etch stop section 17 is disposed on the bottom of the word line 121 and the planar section 18 is filled in the etch stop section 17. While etching the word line layer 120 in the first trench 111 to form the loop structure, etching stops when the etch stop section 17 is reached.

In some implementations, as shown in FIGS. 1 and 2, the semiconductor device 10 further includes a plurality of channel structures 110 arranged with intervals in the first lateral direction between adjacent word line groups 12 and separating structures 19. The plurality of channel structures 110, the plurality of word line groups 12 and the plurality of bit lines (not shown) can constitute a plurality of memory cell transistor structures.

In some examples, the semiconductor device 10 includes a plurality columns of channel structures 110 arranged successively in the first lateral direction and the plurality of channel structures 110 in each column of channel structures 110 are arranged successively in the second lateral direction. Herein, the channel structures 110 extend in the second lateral direction. When a channel structure 110 is located between two adjacent word line groups 12, the two ends of the channel structure 110 extend to the two word line groups 12 respectively. When a channel structure 110 is located between adjacent word line group 12 and separating structure 19, one end of the channel structure 110 extends to the word line group 12, and the other end extends to the separating structure 19.

Herein, it is possible to form a plurality of third trenches 113 extending in the second lateral direction in the substrate 11. Each third trench 113 is disposed to intersect the plurality of first trenches 111 and the plurality of second trenches 112. The plurality of third trenches 113 are arranged with intervals successively in the first lateral direction. A column of channel structures 110 are formed between two adjacent third trenches 113.

An implementation of the present application further provides a memory system including a semiconductor device that is the semiconductor device in any one of the above-described implementations. Since the memory system provided in the implementation of the present application adopts the technical schemes of all the above-described implementations, it has all the beneficial effects brought about by the above-described implementations, which will not be described any more herein.

As shown in FIG. 17, the memory system 1 includes a semiconductor device 10 and a controller 20 coupled with the semiconductor device 10 and configured to control the semiconductor device 10 to implement data writing and reading operations. Herein, the semiconductor device 10 may be an array memory device or a memory bound with CMOS (complementary metal oxide semiconductor) peripheral circuits.

In some examples, the semiconductor device 10 may be stacked with the peripheral circuits or disposed staggered with peripheral circuits, which is not limited herein. The peripheral circuits are electrically connected with the semiconductor device 10 to communicate signals with the semiconductor device 10. The peripheral circuits may be configured to implement logical operations and control and detect on-off states of memory cells in the above-mentioned semiconductor device 10 via metal lines for data storing and reading.

In some examples, the above-mentioned memory may be a three-dimensional memory such as 3D DRAM memory and 3D NAND memory.

In some examples, the controller 20 may control the semiconductor device 10 via a channel CH and the semiconductor device 10 may execute operations based on the control by the controller 20 in response to the request from the host 30. The semiconductor device 10 may receive a command CMD and an address ADDR from the controller 20 through the channel CH and access regions selected from the memory cell array in response to the address. In other words, the semiconductor device 10 may execute internal operations corresponding to the command on the regions selected by the address.

In some implementations, the memory system 1 may be implemented as multimedia cards such as universal flash storage (UFS) device, solid state hard disk (SSD), MMC, cMMC, RS-MMC and mini-MMC, secure digital cards such as SD, mini-SD and micro-SD, storage devices of Personal Computer Memory Card International Association (PCMCIA) card type, storage devices of peripheral component interconnect (PCI) type, storage devices of PCI Express (PCI-E) type, compact flash (CF) cards, smart media cards or memory sticks etc.

In some examples, the above-described memory system 1 may be used in computers, televisions, set-top boxes, on-vehicle terminal products.

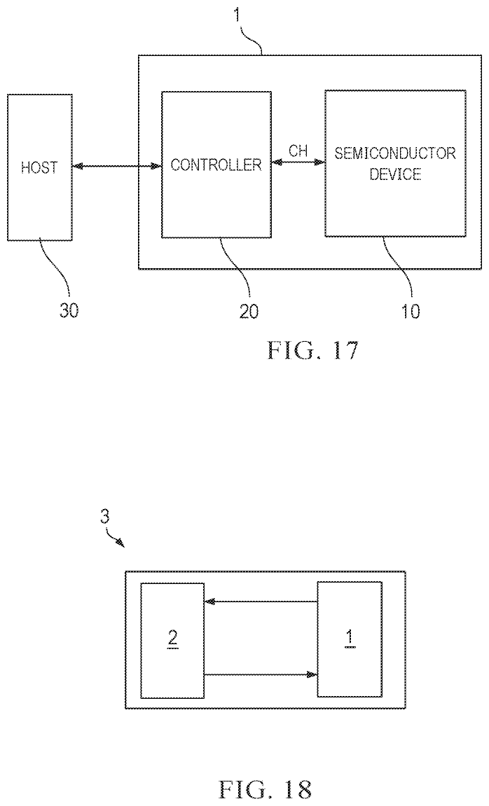

An implementation of the present disclosure further provides an electronic apparatus. As shown FIG. 18, the electronic apparatus 60 includes a central processor 2 and the above-described memory system 1 provided in the implementations of the present application. In some examples, the electronic apparatus 3 may be any device that may store data such as a mobile phone, a desktop computer, a tablet computer, a notebook computer, a server, an on-vehicle device, a wearable device, a mobile power source, etc.

The central processor 2 is configured to exchange information and data with the memory system 1.

Since the memory system provided in implementations of the present application is provided, the electronic device provided in the implementation of the present application has the same beneficial effects as the above-described memory system.

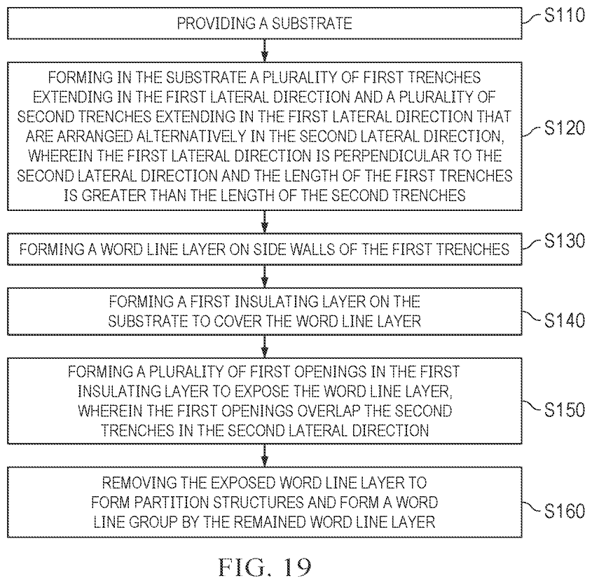

To better fabricate the semiconductor device in the implementations of the present application, an implementation of the present application further provides a fabrication method of a semiconductor device as shown in FIG. 19, including operations S110 to S160 as described in detail below.

S110, providing a substrate.

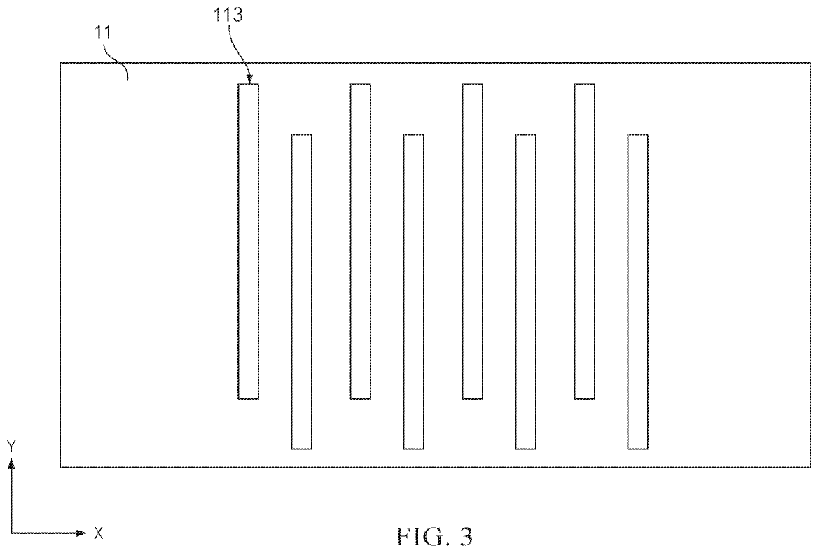

Herein, as shown in FIG. 3, the material for the substrate 11 may be silicon (Si).

S120, forming a plurality of first trenches extending in the first lateral direction and a plurality of second trenches extending in the first lateral direction that are arranged alternatingly in the second lateral direction in the substrate, wherein the first lateral direction is perpendicular to the second lateral direction and the length of the first trench is greater than the length of the second trench.

Herein, as shown in FIG. 3, it is possible to form the plurality of first trenches 111 and the plurality of second trenches 112 extending in the first lateral direction by etching the surface of the substrate 11. The plurality of first trenches 111 are arranged with intervals in the second lateral direction. There is a second trench 112 between adjacent two first trenches 111. It is possible to dispose the second trench 112 to have equal distances from the two first trenches 111 on two sides. S130, forming a word line layer on side walls of the first trench.

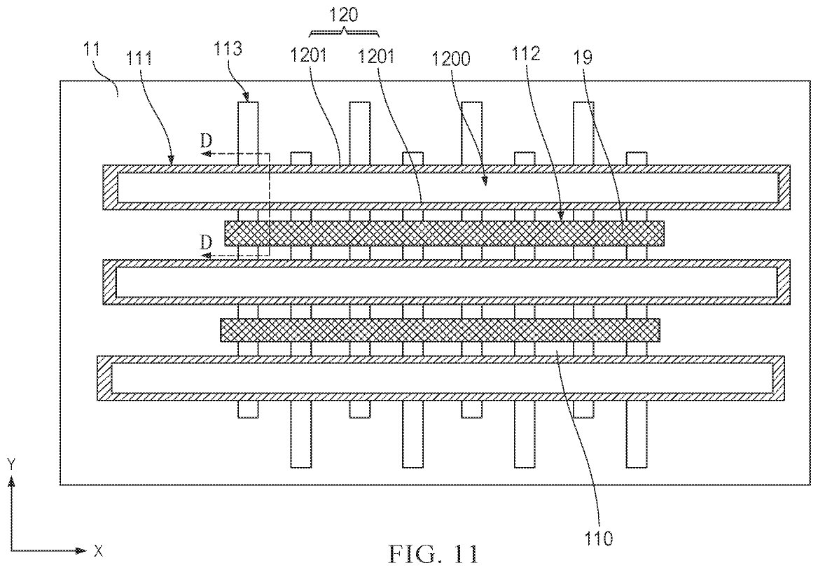

As shown in FIGS. 11 and 12, the word line layer 120 is a loop structure extending circumferentially along the first trench 111 on side walls of the first trench 111. The material for the word line layer 120 may be tungsten (W) or other metal materials.

S140, forming a first insulating layer on the substrate to cover the word line layer.

As shown in FIG. 12, the material for the first insulating layer 13 may be an oxide insulating layer or other insulating materials deposited by chemical vapor deposition (CVD).

S150, forming a plurality of first openings in the first insulating layer to expose the word line layer, wherein the first openings overlap the second trenches in the second lateral direction.

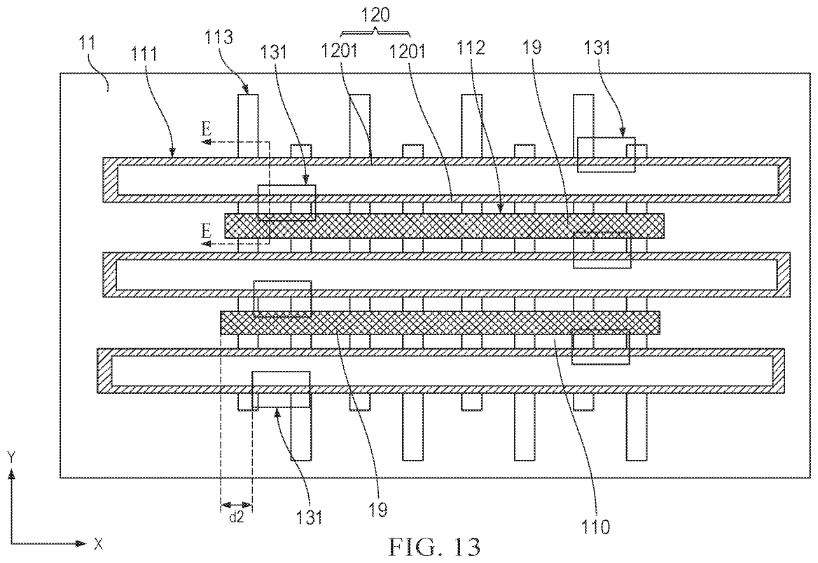

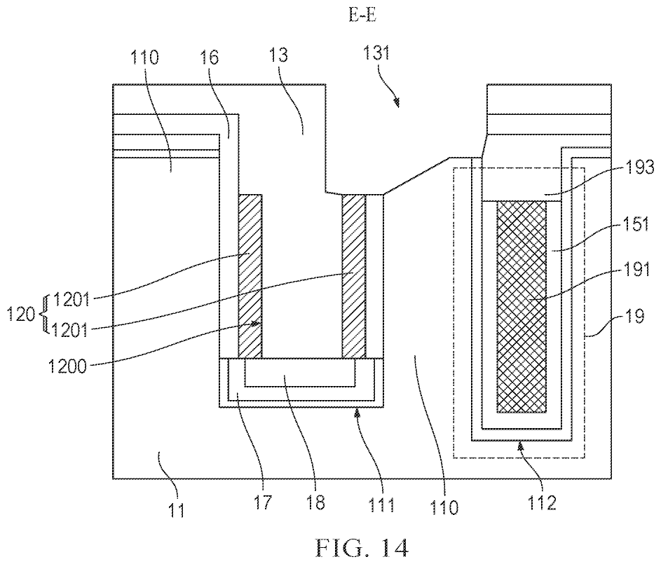

As shown in FIGS. 13 and 14, it is possible to make two first openings 131 to correspond to one first trench 111. The two first openings 131 corresponding to the first trench 111 are arranged on both sides of the first trench 111 in the first lateral direction. The word line layer 120 includes two word line segments 1201 arranged on two side walls of the first trench 111 in the first lateral direction. The two ends of each of the two word line segments 1201 in the second lateral direction are connected with each other correspondingly. The two first openings 131 expose a part of the two word line segments 1201 respectively.

Herein, it is possible to have one first opening 131 corresponding to the first trench 111 to overlap the second trench 112, and it is also possible to have the two first openings 131 corresponding to the first trench 111 to overlap the second trench 112 respectively. Further, it is possible to have a part of the first openings 131 corresponding to the first trench 111 to overlap the second trench 112, and it is also possible to have the entire first openings 131 to overlap the second trench 112.

In some examples, as shown in FIG. 13, in the top view direction of the semiconductor device 10 (i.e., in the direction perpendicular to the first lateral direction and the second lateral direction), there is overlap between one first opening 131 and a part of one word line 121 segment of the word line layer 120, and there is overlap between another first opening 131 and a part of another word line 121 segment of the word line layer 120.

S160, removing the exposed word line layer to form partition structures and form a word line group by the remained word line layer.

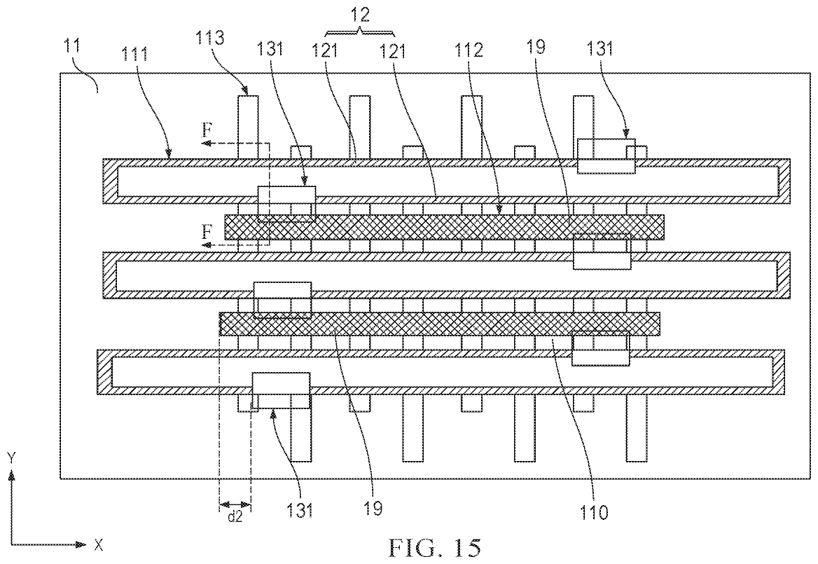

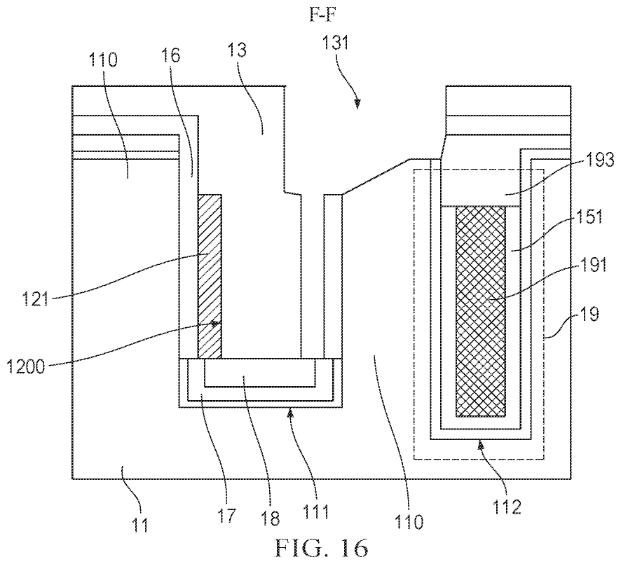

As shown in FIGS. 15 and 16, by removing parts of the word line layer 120 that are exposed by the first openings 131, it is possible to form partition structures 123 at the first openings 131 and break the word line layer 120 at the first openings 131, thereby breaking the un-exposed parts of the word line layer 120 to form the word line group 12 having two word lines 121.

With the fabrication method of the semiconductor device 10 as provided in the implementations of the present application, a plurality of first openings 131 exposing the word line layer 120 are formed on the first insulating layer 13 and the first openings 131 and the second trenches 112 overlap in the second lateral direction. After forming the partition structures 123 and the word line groups 12 by removing exposed word line layer 120, the partition structures 123 and the second trenches 112 overlap in the second lateral direction perpendicular to the first lateral direction such that the overlapping regions S of the two word lines 121 of the word line group 12 are far away from the shifting regions M of the second trenches 112 on at least a side of the first lateral direction, such that there is a reduced risk of patterning shift for parts of the two word lines 121 of the word line group 12 that are in the overlapping regions S. The gap between the two word lines 121 in the overlapping region S can penetrate through the whole word line group 12 such that parts of the two word lines 121 of the word line group 12 in the overlapping region S remain in separated state, thereby reducing the risk of remaining connected for the two word lines 121 of the word line group 12 due to the patterning shifts in the process of forming the word line group 12 by etching.

In some implementations, as shown in FIGS. 13 and 15, the orthogonal projection of a first opening 131 in the second lateral direction with respect to the second trench 112 is within a second trench 112, and then the orthogonal projection of a partition structure 123 in the second lateral direction with respect to a separating structure 19 is also within the separating structure 19. That is, all partition structures 123 overlap the separating structures 19 such that overlapping regions S in which the two word lines 121 of the word line group 12 overlap in the second lateral direction are farther away from the shifting regions M so as to further reduce the risk of interconnection between two word lines 121 of the word line group 12.

Herein, in the top view direction of the semiconductor device 10, the first openings 131 and the side edges of ends of the second trenches are disposed with intervals. Then, in the top view direction of the semiconductor device 10, the partition structures 123 and side edges of ends of the separating structures 19 are also disposed with intervals such that the distances between overlapping regions S of the word line group 12 and the shifting regions M are increased so as to further reduce the risk of interconnection between two word lines 121 of the word line group 12.

As shown in FIG. 15, in the second lateral direction, the distance d2 between a first opening 131 and a side edge of an end of a second trench 112 is greater than or equal to 200 nm, such that the distance d1 between a partition structure 123 and a side edge of an end of a separating structure 19 is greater than or equal to 200 nm so as to reduce the risk of interconnections between two word lines 121 of a word line group 12 as much as possible. Herein, the distance d2 between a first opening 131 and a side edge of an end of a second trench 112 may be 210 nm, 250 nm, 300 nm, etc. in some examples, depending on the structure of the semiconductor device 10.

Of course, in the second lateral direction, when the distance d2 between a first opening 131 and a side edge of an end of a second trench 112 is less than 200 nm, the distance d1 between a partition structure 123 and a side edge of an end of a separating structure 19 is also less than 200 nm, which can also reduce the risk of interconnections between two word lines 121 of a word line group 12 to a certain degree.

In some implementations, removing the exposed word line layer 120 to form the partition structures 123 in the above-described operation S160 includes:
S161, removing the exposed word line layer.
S162, forming a second insulating layer on the substrate to fill the first openings, thereby forming partition structures.

Herein, as shown in FIG. 16, it is possible to remove the exposed word line layer 120 by etching. Then, as shown in FIG. 2, depositing the second insulating layer 14 on the substrate 11 can allow partial material of the second insulating layer 14 to fill in the first openings 131 so as to form partition structures 123 for partitioning the two word lines 121 of the word line group 12 in the first openings 131.

In some implementations, prior to forming the word line layer on side walls of the first trenches, the fabrication method of the semiconductor device as provided in the implementations of the present application further includes operations S121 to operation S123 as described in detail below.

S121, forming a third insulating layer in the second trenches.

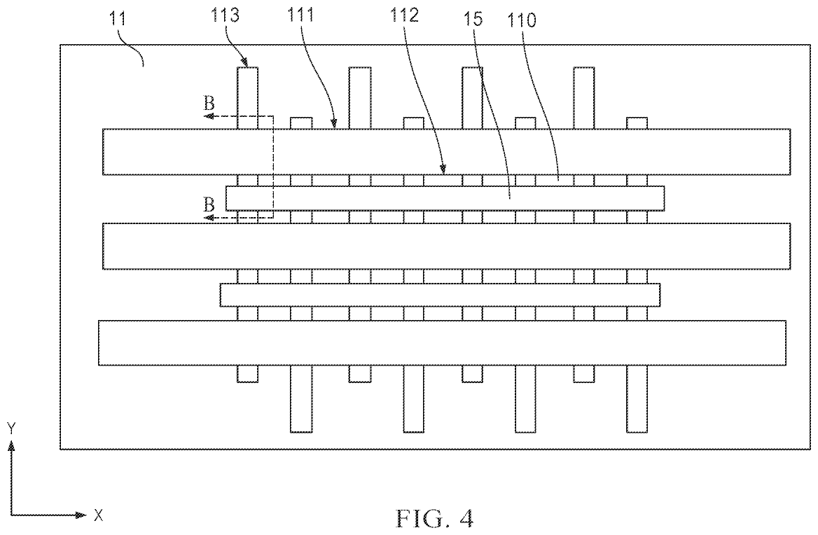

Herein, as shown in FIGS. 4 and 5, it is possible to deposit the third insulating layer 15 on a side of the substrate 11 on which the second trenches 112 are disposed.

S122, forming second openings in the third insulating layer by patterning to form the first insulating sections.

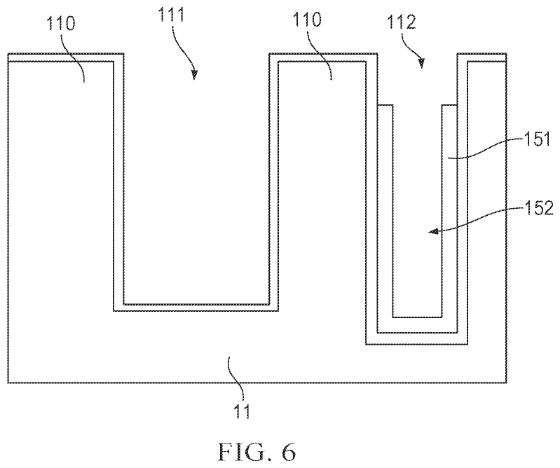

As shown in FIG. 6, it is possible to pattern the third insulating layer 15 by etching process to form the second openings 152 in parts of the third insulating layer 15 that are within the second trenches 112, thereby forming the first insulating sections 151 located in the second trenches 112.

S123, filling the metal sections in the second openings.

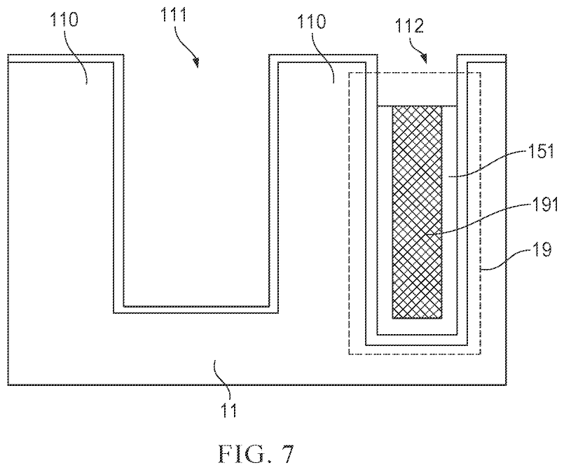

As shown in FIG. 7, it is possible to deposit a layer of metal on the surfaces of the third insulating layer 15 and the substrate 11 by deposition to form the metal sections 191 filled in the second openings 152. Then, parts of the metal layer other than the metal sections 191 are removed by etching and metal sections 191 inside the second openings 152 are remained.

In some implementations, after the above-described operation of filling the metal sections in the second openings, the fabrication method of the semiconductor device as provided in the implementations of the present application further includes: forming second insulating sections on the metal sections and the first insulating sections, wherein the first openings expose the second insulating sections and the substrate.

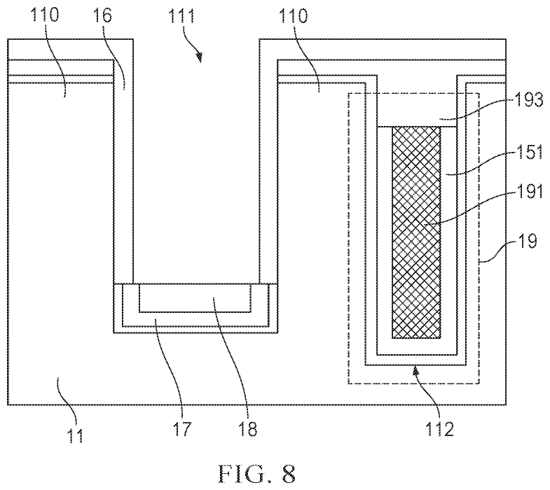

As shown in FIG. 8, by forming second insulating sections 193 on the metal sections 191 and the first insulating sections 151 and exposing the second insulating sections 193 and the substrate 11 via the first openings 131, the metal sections 191 are intact while removing parts of the word line group 12 exposed via the first openings 131 by etching.

In some implementations, the above-described operation S130 of forming the word line layer on side walls of the first trenches includes operation S131 to S135 as described in detail below.
S131, forming a fourth insulating layer on side walls and bottom of the first trench. S132, forming a etch stop section on side walls and bottom of the first trench.
S133, forming a planar section inside the etch stop section.
S134, forming a word line material layer in the first trench.
S135, forming the word line material layer into a word line layer disposed on side walls of the first trench by patterning.

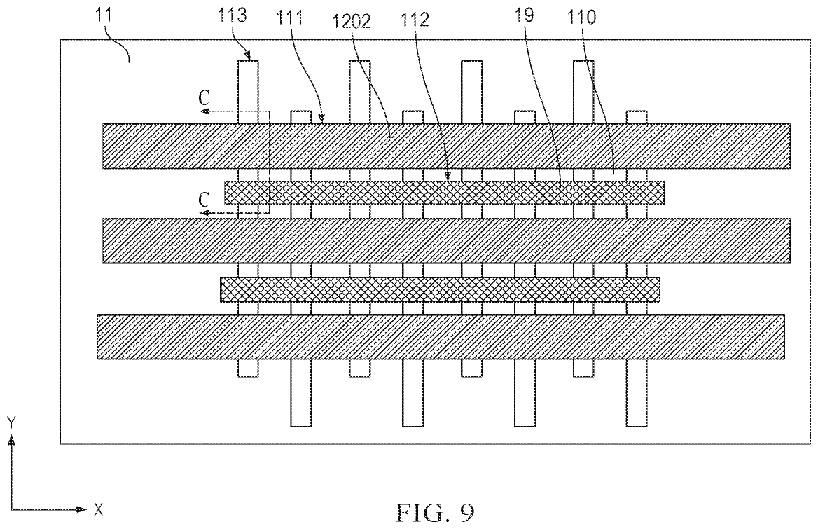

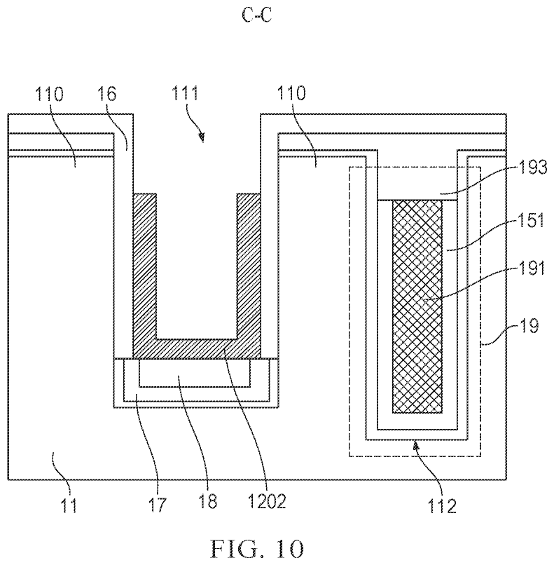

Herein, as shown in FIG. 8, it is possible to deposit an insulating material on the surface of the substrate 11 on which the first trenches 111 are disposed by deposition process to form the fourth insulating layer 16 on side walls and bottoms of the first trenches 111. After forming the word line material layer 1202 in the first trench 111 (as shown in FIGS. 9 and 10), it is possible to pattern the word line material layer 1202 by etching to form an etch trench 1200 (as shown in FIG. 12) extending to the etch stop section 17 and the planar section 18 in the word line material layer 1202 such that the word line material layer 1202 is formed into the word line layer 120 disposed on side walls of the first trench 111.

In some implementations, before the above-described operation S120 of forming a plurality of first trenches extending in the first lateral direction and a plurality of second trenches extending in the first lateral direction in the substrate, the fabrication method of the semiconductor device as provided in the implementations of the present application further includes: forming a plurality of third trenches extending in the second lateral direction in the substrate. Herein, the plurality of first trenches, the plurality of second trenches and the plurality of third trenches intersect each other to form a plurality of channel structures that are disposed with intervals in the first lateral direction between adjacent word line groups and second trenches.

As shown in FIG. 1, by having the plurality of first trenches 111 and the plurality of second trenches 112 to extend in the first lateral direction and be arranged alternatingly with intervals in the second lateral direction, and at the same time having the plurality of third trenches 113 to extend in the second lateral direction and be arranged with intervals successively in the first lateral direction, the plurality of first trenches 111, the plurality of second trenches 112 and the plurality of third trenches 113 intersect each other to form the plurality of channel structures 110. Herein, the plurality of channel structures 110 are divided into columns in the first lateral direction. Each column of channel structures 110 includes a plurality of channel structures 110 arranged with intervals successively in the second lateral direction and the plurality of channel structures 110 in a same column of channel structures 110 are arranged with intervals in the first lateral direction between adjacent word line groups 12 and second trenches 112.

The semiconductor device, the fabrication method thereof, and the memory system provided in implementations of the present application have been described in detail above. Specific examples are used herein to set forth the principle and implementations of the present application and description of the above implementations is only for assisting understanding the method and gist thereof of the present application. Meanwhile, those skilled in the art may make modifications to implementations and application ranges according to the idea of the present application. In summary, the contents of the present specification should not be construed as limiting the present application.

What is claimed is:

1. A semiconductor device, comprising:
a plurality of word line groups and separating structures disposed between two adjacent word line groups of the plurality of word line groups, the plurality of word line groups and the separating structures extending in a first lateral direction, and a length of the plurality of word line groups being greater than a length of the separating structures in the first lateral direction;
wherein each of the plurality of word line groups comprises two word lines and two partition structures in a same word line group, the word lines and the partition structures are disposed alternatingly as a closed loop, and in a second lateral direction perpendicular to the first lateral direction, there are overlaps between the partition structures and the separating structures.

2. The semiconductor device of claim 1, wherein orthogonal projections of the partition structures in the second lateral direction are within the separating structures.

3. The semiconductor device of claim 2, wherein in a top view direction of the semiconductor device, the partition structures and side edges of ends of the separating structures are disposed with intervals.

4. The semiconductor device of claim 3, wherein in the second lateral direction, a distance d1 between the partition structures and side edges of ends of the separating structures is greater than or equal to 200 nm.

5. The semiconductor device of claim 1, wherein each of the separating structures comprises a gas cavity.

6. The semiconductor device of claim 1, wherein each of the separating structures comprises a metal section.

7. The semiconductor device of claim 1, wherein each of the separating structures comprises a metal section, a first insulating section and a second insulating section;
wherein the first insulating section is disposed on side walls and a bottom of the metal section, and the second insulating section is disposed on a top of the metal section and a top of the first insulating section.

8. The semiconductor device of claim 1, wherein the semiconductor device further comprises an etch stop section and a planar section at a bottom of each of the plurality of word line groups;
wherein the etch stop section is disposed at a bottom of each of the plurality of word line groups and the planar section is filled in the etch stop section.

9. The semiconductor device of claim 1, wherein the semiconductor device further comprises a plurality of channel structures disposed with intervals in the first lateral direction between the two adjacent word line groups and the separating structures.

10. The semiconductor device of claim 1, wherein each of the partition structures comprises an insulating material.

11. A fabrication method of a semiconductor device, comprising:
providing a substrate;
forming a plurality of first trenches extending in a first lateral direction and a plurality of second trenches extending in the first lateral direction in the substrate, wherein the first trenches and the second trenches are arranged alternatingly in a second lateral direction perpendicular to the first lateral direction, and a length of the first trenches is greater than a length of the second trenches;
forming a word line layer on side walls of the first trenches;
forming a first insulating layer on the substrate to cover the word line layer;
forming a plurality of first openings in the first insulating layer to expose the word line layer, wherein the first openings overlap the second trenches in the second lateral direction; and
removing the exposed word line layer to form partition structures and to form a word line group by a remaining word line layer.

12. The fabrication method of the semiconductor device of claim 11, wherein orthogonal projections of the partition structures in the second lateral direction with respect to the second trenches are within the second trenches, and in a top view direction of the semiconductor device, the partition structures and side edges of ends of the second trenches are disposed with intervals.

13. The fabrication method of the semiconductor device of claim 11, wherein the removing the exposed word line layer to form partition structures comprises:
removing the exposed word line layer; and
forming a second insulating layer on the substrate to fill the first openings, thereby forming partition structures.

14. The fabrication method of the semiconductor device of claim 11, wherein two of the first openings correspond to one of the first trenches.

15. The fabrication method of the semiconductor device of claim 11, wherein, before the forming the word line layer on side walls of the first trenches, the method further comprises:
forming a third insulating layer in the second trenches;
forming second openings in the third insulating layer by patterning to form the first insulating sections; and
filling metal sections in the second openings.

16. The fabrication method of the semiconductor device of claim 15, wherein, after the filling the metal sections in the second openings, the method further comprises:
forming second insulating sections on the metal sections and the first insulating sections;
wherein the first openings expose the second insulating sections and the substrate.

17. The fabrication method of the semiconductor device of claim 11, wherein the forming the word line layer on side walls of the first trenches comprises:
forming a fourth insulating layer on side walls and bottom of the first trenches;
forming a etch stop section on side walls and bottom of the first trenches;
forming a planar section inside the etch stop section;
forming a word line material layer in the first trenches; and
forming the word line material layer into a word line layer disposed on side walls of the first trenches by patterning.

18. The fabrication method of the semiconductor device of claim 11, wherein before the forming the plurality of first trenches extending in the first lateral direction and the plurality of second trenches extending in the first lateral direction in the substrate, the method further comprises:
forming a plurality of third trenches extending in the second lateral direction in the substrate;
wherein the plurality of first trenches, the plurality of second trenches, and the plurality of third trenches intersect each other to form a plurality of channel structures that are disposed with intervals in the first lateral direction between adjacent word line groups and the second trenches.

19. A memory system, comprising:
a semiconductor device, comprising:
a plurality of word line groups and separating structures disposed between two adjacent word line groups of the plurality of word line groups, the plurality of word line groups and the separating structures extending in a first lateral direction, and a length of the plurality of word line groups being greater than a length of the separating structures in the first lateral direction;
wherein each of the plurality of word line groups comprises two word lines and two partition structures in a same word line group, the word lines and the partition structures are disposed alternatingly as a closed loop, and in a second lateral direction perpendicular to the first lateral direction, there are overlaps between the partition structures and the separating structures; and
a controller coupled to the semiconductor device and configured to control the semiconductor device to implement data writing and reading operations.
